(19) United States
(12) Patent Application Publication
(10) Pub. No.: US 2020/0287069 A1
(43) Pub. Date: Sep. 10, 2020

(54) NONPOLAR III-NITRIDES SOLAR CELL DEVICE

(71) Applicants: Xuanqi Huang, Tempe, AZ (US); Yuji Zhao, Chandler, AZ (US)

(72) Inventors: Xuanqi Huang, Tempe, AZ (US); Yuji Zhao, Chandler, AZ (US)

(21) Appl. No.: 16/811,355

(22) Filed: Mar. 6, 2020

Related U.S. Application Data
(60) Provisional application No. 62/815,814, filed on Mar. 8, 2019.

(51) Int. Cl. H01L 31/0735; H01L 31/0304; H01L 31/0352; H01L 31/0224

(52) U.S. Cl. CPC H01L 31/0735; H01L 31/03042; H01L 31/03048; H01L 31/022433; H01L 31/035236

(57) ABSTRACT

A solar cell including a nonpolar m-plane GaN substrate, an n-type III-nitride layer, a III-nitride active region, and a p-type III-nitride layer. In one example, the solar cell includes a nonpolar m-plane GaN substrate, a Si-doped GaN layer, a multiplicity of InGaN/GaN layers, and and a Mg-doped GaN layer. A working temperature range of the solar cell is from room temperature to about 500° C., an external quantum efficiency of the solar cell increases by at least a factor of 2 from room temperature to 500° C., and a temperature coefficient of the solar cell is greater than zero up to 350° C.

### CROSS-REFERENCE TO RELATED APPLICATION

This application claims the benefit of U.S. Patent Application No. 62/815,814 entitled “NONPOLAR III-NITRIDES SOLAR CELL DEVICE” filed on Mar. 8, 2019, which is incorporated by reference herein in its entirety.

### STATEMENT OF GOVERNMENT INTEREST

This invention was made with government support under NNX15AU48G awarded by National Aeronautics and Space Administration. The government has certain rights in the invention.

### TECHNICAL FIELD

This invention relates to a nonpolar III-nitrides solar cell device, including a solar cell employing InGaN alloy layer as an absorbing active region.

### BACKGROUND

Conventional InGaN solar cells typically suffer from the polarization-related effects from the adoption of c-plane sapphire substrates, which impact the efficiency of InGaN solar cells at both the room temperature (RT) and high temperatures. At RT, the large polarization-induced electric field inside the InGaN/GaN QWs typically lead to a large quantum barrier that hinders the carrier collection in solar cells. At high temperatures, the polarization-related effects are convoluted with thermal escaping, making it even more challenging to probe, analyze and engineer the carrier dynamics of InGaN solar cells.

### SUMMARY

Fabrication of III-nitride solar cells using polarization-free (i.e., nonpolar) InGaN/GaN multiple-quantum-wells (MQW) is described. These InGaN solar cells show a large working temperature range from room temperature (RT) to 500° C., with positive temperature coefficients up to 350° C. The peak external quantum efficiencies (EQEs) of the devices show a 2.5-fold enhancement from RT (˜32%) to 500° C. (˜81%). This can be attributed at least in part to an increase of over 70% in carrier lifetime in nonpolar InGaN MQW solar cells obtained from time-resolved photoluminescence (TRPL) measurements.

In a first general aspect, a solar cell includes a nonpolar m-plane GaN substrate, an n-type III-nitride layer, a III-nitride active region, and a p-type III-nitride layer.

Implementations of the first general aspect may include one or more of the following features.

The n-type III-nitride layer is in direct contact with the nonpolar m-plane GaN substrate. The III-nitride active region is in direct contact with the nonpolar m-plane GaN substrate. The III-nitride active region includes one or more indium-containing quantum wells with barriers. The p-type III-nitride layer is in direct contact with the III-nitride active region.

In a second general aspect, a solar cell includes a nonpolar m-plane GaN substrate, a Si-doped GaN layer, a multiplicity of InGaN/GaN layers, and a Mg-doped GaN layer.

Implementations of the second general aspect may include one or more of the following features.

The Si-doped GaN layer includes a silicon-doped n-GaN layer. The Si-doped GaN layer further includes a silicon-doped n⁺-GaN layer. The multiplicity of InGaN/GaN layers define multiple quantum wells. The Mg-doped GaN layer includes a Mg-doped smooth p⁺-GaN layer. The Mg-doped GaN layer further includes a Mg-doped p-GaN layer. The Mg-doped GaN layer further includes a Mg-doped p⁺-GaN contact layer.

The solar cell includes an n-metal contact on the Si-doped GaN layer. The n-metal contact includes a Ti/Al/Ni/Au grid contact. The solar cell includes a p-metal contact on the Mg-doped GaN layer. The p-metal contact includes a Ni/Au grid contact.

Implementations of the first and second general aspects may include one or more of the following features.

A working temperature range of the solar cell is from room temperature to about 500° C. An external quantum efficiency of the solar cell increases by at least a factor of 2 from room temperature to 500° C. A temperature coefficient of the solar cell is greater than zero up to 350° C.

The details of one or more embodiments of the subject matter of this disclosure are set forth in the accompanying drawings and the description. Other features, aspects, and advantages of the subject matter will become apparent from the description, the drawings, and the claims.

### BRIEF DESCRIPTION OF THE DRAWINGS

FIGS. 1A and 1B depict the crystal planes of the polar c-plane and the nonpolar m-plane GaN, respectively. FIGS. 1C and 1D depict energy band diagrams of the active InGaN/GaN multiple quantum well (MQW) regions of the two crystal planes.

FIG. 2 is a schematic device structure for a fabricated nonpolar InGaN solar cell.

### DETAILED DESCRIPTION

This disclosure describes III-nitride solar cells having polarization-free (i.e., nonpolar) InGaN/GaN multiple-quantum-wells (MQW). These InGaN solar cells demonstrate a large working temperature range from room temperature (RT) to 500° C., with positive temperature coefficients up to 350° C. The peak value of external quantum efficiencies (EQEs) of the devices show a 2.5-fold enhancement from RT (˜32%) to 500° C. (˜81%).

### High-Temperature Characterizations of the Nonpolar InGaN/GaN MQW Solar Cells

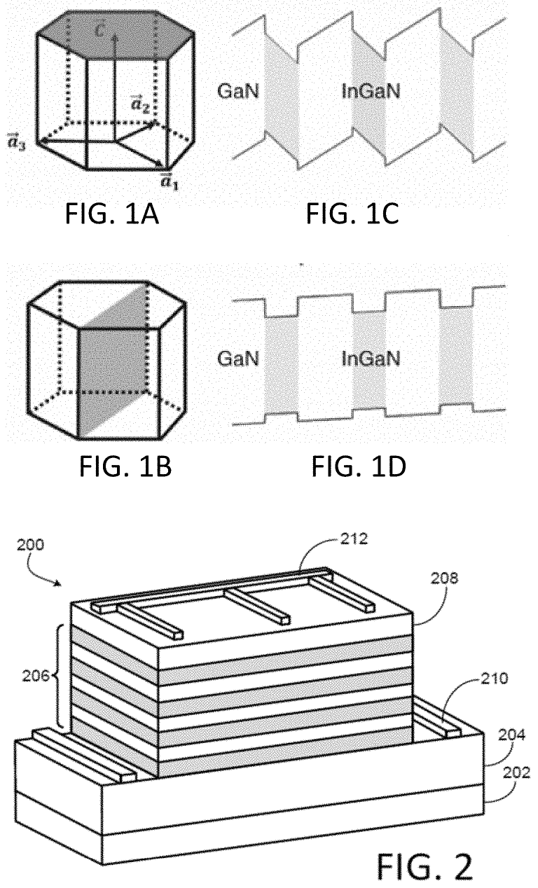

FIGS. 1A and 1B depict schematic crystal planes of the polar c-plane and the nonpolar m-plane GaN, respectively. FIGS. 1C and 1D show the schematic zoom-in energy band diagrams of the active InGaN/GaN MQW regions of the two crystal planes, respectively. As depicted in FIG. 1C, due to the large polarization-related effects, the energy band diagram of the MQWs on the conventional polar c-plane GaN is tilted. In contrast, as depicted in FIG. 1D, the energy band diagram of the MQWs on the polarization-free nonpolar m-plane is flat. The distinct energy band profiles between two cases impacts the carrier transport, leading to different solar cell device performance under high temperatures.

FIG. 2 depicts fabricated nonpolar InGaN solar cell 200. Solar cell 200 includes m-plane GaN substrate 202, Si-doped n-GaN layer 204, InGaN/GaN MQW structure 206, and Mg-doped p-GaN layer 208. A thickness of Si-doped n-GaN layer 204 can be about 1 μm. In some implementations, Si-doped GaN layer 204 includes a Si-doped n-GaN layer on Mg-doped p-GaN layer 208 and a Si-doped n⁺-GaN layer on the Si-doped n-GaN layer. A Si content of the Si-doped n⁺-GaN layer may exceed that of the Si-doped n-GaN by an order of magnitude. InGaN/GaN MQW structure 206 can include multiple alternating layers of InGaN and GaN (e.g., 10 to 30 InGaN layers alternating with 10 to 30 GaN layers, respectively). A thickness of the InGaN and GaN layers can be in a range of about 1 nm to about 20 nm each (e.g., about 5 nm or about 10 nm). Mg-doped p-GaN layer 208 can include a Mg-doped smooth p⁺-GaN layer on InGaN/GaN MQW structure 206, a Mg-doped p-GaN layer on the Mg-doped smooth p⁺-GaN layer, and a Mg-doped p⁺-GaN contact layer on the Mg-doped p-GaN layer. A Mg content of the Mg-doped p⁺-GaN contact layer may exceed that of the Mg-doped smooth p⁺-GaN layer and the Mg-doped p-GaN by an order of magnitude. A thickness of Mg-doped p-GaN layer 208 can be in a range of about 100 nm to about 200 nm. Solar cell 200 also includes n-contact metal grid 210 (e.g., Ti/Al/Ni/Au) on n-GaN:Si layer 204 and p-contact metal grid 212 (e.g., Ni/Au) on p-GaN:Mg layer 208.

### EXAMPLE

Growth and structure parameters of nonpolar InGaN. InGaN MQW solar cells on nonpolar m-plane substrates were grown by conventional metal-organic chemical vapor deposition (MOCVD). The growth condition was designed to achieve indium incorporation of about 15% in samples. Layers in the designed device include a 1 μm Si-doped n-GaN ([Si]=5×10¹⁸ cm⁻³), 10 nm highly Si-doped n⁺-GaN ([Si]=1×10¹⁹ cm⁻³), 20 periods of InGaN (6 nm)/GaN (10 nm) MQWs, 30 nm Mg-doped smooth p⁺-GaN ([Mg]=1×10¹⁹ cm⁻³), 120 nm Mg-doped p-GaN ([Mg]=3×10¹⁹ cm⁻³), and 10 nm highly Mg-doped p⁺-GaN contact layer ([Mg]=1×10²⁰ cm⁻³). None of these devices is coated with traditional ITO or current spreading layers.

Solar cell fabrication and characterization. The InGaN solar cell samples were processed into 1 mm×1 mm mesas by standard contact lithography and inductively coupled plasma (ICP) etching. Ti/Al/Ni/Au and Ni/Au grid contacts deposited via electron beam evaporation were employed as n and p metal contacts, respectively.

HRXRD measurement. The nonpolar InGaN solar cell sample was characterized by high-resolution X-ray diffraction measurement using PANalytical X'Pert Pro materials research X-ray diffractometer (MRD) system with Cu Kα radiations. Hybrid monochromator and triple axis module are used for the incident and diffracted beam optics, respectively.

FIB and STEM imaging. The nonpolar InGaN solar cell specimens for STEM imaging were prepared with an FEI Nova 200 Dual-Beam FIB system with a Ga ion source. A JEOL-ARM200F scanning transmission electron microscopy (STEM) operated at 200 KV and equipped with double aberration-correctors for both probe-forming and imaging lenses was used to perform high-angle annular-dark field (HAADF) imaging. The compositional distribution of In element in MQW layers was accomplished by acquiring the energy-dispersive X-ray (EDX) spectroscopic spectra of In element.

Illuminated current density-voltage (JV) and EQE measurement. Solar cell parameters such as the open-circuit voltage, fill factor and power conversion efficiency were extracted from LIV measurements taken using an Oriel Class A Solar Simulator. The Newport Class A solar simulator generates a 4-inch-diameter collimated beam using a xenon arc lamp and a series of filters designed to provide 0.1 Wcm² at the surface of the testing stage. All JV curves of InGaN and GaAs cells were taken at 1 sun condition AM1.5G spectrum.

EQE measurement data were collected using under short-circuit conditions using an Oriel QEPVSI quantum efficiency measurement system and calibrated with a reference Si photodetector. This system is composed of a 150 W Xenon arc lamp coupled with a Cornerstone 260¼m monochromator.

The nonpolar InGaN solar cell sample is around 0.55 cm×0.55 cm, which is slightly larger than the mesa area of one GaAs cell (0.5 cm×0.5 cm).

A Linkam HFS600-PB4 stage capable of heating the samples up to 600° C. was used to perform the temperature-dependent measurements. For both the external quantum efficiency (EQE) and current-voltage (I-V) measurements, the temperature of the stage was increased from room temperature to 500° C. in steps of 25-50° C. with a ramp rate of 10-20° C./min. Once the desired temperature was reached, the sample was kept at the specified temperature for another 3 min. The experimental setup did not allow for the simultaneous acquisition of the temperature-dependent EQE and I-V. Therefore, these measurements were performed on the same InGaN cell while separately on different cells on the same GaAs wafer. For the EQE and I-V measurements for filtered GaAs cell, InGaN solar cell sample was carefully placed on top of GaAs cell when the desired temperature was reached and it was at the open-circuit state.

Photoluminescence and time-resolved photoluminescence measurements. PL and TRPL measurements were done using a home-built system, where a picosecond 405 nm pulsed laser diode (PDL 800-B) was used as excitation source. PL spectrum was collected by a Si array detector coupled with Horiba monochromator (TRIAX 320). TRPL was measured by a time-correlated single-photon counting system (TCSPC). A Si photomultiplier tube (PMT) detector is attached at the other output port of monochromator and its signal is then recorded by TCSPC board (SPC130 module).

Transmission and reflection spectra measurement. The transmission and reflectance spectra of the fabricated nonpolar InGaN solar cell sample were characterized with LAMBDA 950/1050 UV/VIS/NIR Spectrophotometer from Perkin Elmer.

The EQE performance of the fabricated nonpolar InGaN/GaN solar cell was characterized under various temperatures from 25° C. to 450° C. As the temperature increases, the peak EQEs of the nonpolar InGaN solar cell continuously increase from ˜32% at 25° C. to ˜81% at 450° C., in contrast to most solar cells that show a large degradation in EQEs with increasing temperatures. Furthermore, the cutoff wavelengths in the EQE spectral of the nonpolar InGaN solar cells increases as the temperature increases (i.e., from ˜435 nm at 25° C. to ˜480 nm at 450° C.), due to the bandgap narrowing at high temperatures. In comparison, the onset wavelengths in the EQE spectra show minimal changes with increasing temperatures. As a result, broader EQE spectra with enhanced peak EQE values were obtained from the nonpolar InGaN solar cells at high temperatures.

Temperature-dependent illuminated current density-voltage (JV) measurements of the nonpolar InGaN solar cell and extracted V_{oc}, J_{sc}, fill factor (FF) and power conversion efficiency (eff) were also observed. The V_{oc} of the nonpolar InGaN solar cell decreases monotonously at a rate of ˜2.85 mV/° C. in the range of 25° C.-450° C. This is due at least in part to the increased carrier recombination (and thus the increased dark saturation current J₀) as temperature increases. The J_{sc} increases monotonically from 0.52 mA/cm² at 25° C. to 1.91 mA/cm² at 450° C., which suggests a 3.7-fold enhancement. This increase in J_{sc} also corresponds to the enhanced EQE spectra at elevated temperatures.

The FF of the device shows a peak at 200° C. due to the trade-off between V_{oc} and J_{sc}. This rollover phenomena in FF can be ascribed to the trade-off between carrier escape and recombination at high temperatures. As a result, the power convention efficiency of the nonpolar InGaN solar cell increases monotonically from 0.55% at 25° C. to 0.94% at 350° C., and then falls off to 0.812% at 450° C. Based on Shockley-Queisser analysis, the optimal bandgap of the solar cell changes from 1.4 eV at RT to ˜2.0 eV at 500° C. Though Si and GaAs have nearly optimal bandgaps at RT, they deviate from the optimal values as temperature rises, resulting in a reduced efficiency. In contrast, with the tunable bandgap property, III-nitrides can be further engineered to match the optimal value of bandgap for the corresponding temperature (above 450° C.).

The temperature-dependent optical properties and carrier dynamics for nonpolar and polar InGaN MQW samples were studied using photoluminescence (PL) and time-resolved photoluminescence (TRPL) measurements. The power of the pulsed excitation source was chosen to approximate the actual light intensity of solar cells under operation. PL and TRPL spectra from RT to 400° C. of both m- and c-plane samples were observed. The lifetime of m-plane device rises as temperature increases and increases by over 70% at 400° C. compared to itself at RT. This phenomenon may be attributed to the strong radiative recombination ability of m-plane InGaN MQWs. While m-plane InGaN QWs have a large radiative recombination rate compared to c-plane counterparts, c-plane devices have shown an opposite trend compared to the nonpolar device.

Thus, a high performance nonpolar InGaN MQW solar cell for high temperature PV applications (e.g., >350° C.) was fabricated. The single-junction nonpolar m-plane InGaN solar cell exhibited a large positive temperature coefficient for EQE and PV efficiency from RT to 350° C. A 70% efficiency enhancement was observed from RT to 350° C. in this nonpolar InGaN cell. This thermal performance is attributed to several factors, including (i) improved material quality through the homo-epitaxial growth enabled by single-crystal substrates; (ii) enhanced radiative capability due to nonpolar crystal orientation, thus improved effective lifetime of the photogenerated carriers in the QWs; and (iii) narrowed large energy bandgap at high temperatures, offering better matching with solar spectrum.

Although this disclosure contains many specific embodiment details, these should not be construed as limitations on the scope of the subject matter or on the scope of what may be claimed, but rather as descriptions of features that may be specific to particular embodiments. Certain features that are described in this disclosure in the context of separate embodiments can also be implemented, in combination, in a single embodiment. Conversely, various features that are described in the context of a single embodiment can also be implemented in multiple embodiments, separately, or in any suitable sub-combination. Moreover, although previously described features may be described as acting in certain combinations and even initially claimed as such, one or more features from a claimed combination can, in some cases, be excised from the combination, and the claimed combination may be directed to a sub-combination or variation of a sub-combination.

Particular embodiments of the subject matter have been described. Other embodiments, alterations, and permutations of the described embodiments are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional), to achieve desirable results.

Accordingly, the previously described example embodiments do not define or constrain this disclosure. Other changes, substitutions, and alterations are also possible without departing from the spirit and scope of this disclosure.

What is claimed is:

1. A solar cell comprising:
a nonpolar m-plane GaN substrate;
a Si-doped GaN layer;
a multiplicity of InGaN/GaN layers; and
a Mg-doped GaN layer.

2. The solar cell of claim 1, wherein the Si-doped GaN layer comprises a silicon-doped n-GaN layer.

3. The solar cell of claim 2, wherein the Si-doped GaN layer further comprises a silicon-doped n⁺-GaN layer.

4. The solar cell of claim 1, wherein the multiplicity of InGaN/GaN layers define multiple quantum wells.

5. The solar cell of claim 1, wherein the Mg-doped GaN layer comprises a Mg-doped smooth p⁺-GaN layer.

6. The solar cell of claim 5, wherein the Mg-doped GaN layer further comprises a Mg-doped p-GaN layer.

7. The solar cell of claim 6, wherein the Mg-doped GaN layer further comprises a Mg-doped p⁺-GaN contact layer.

8. The solar cell of claim 1, further comprising an n-metal contact on the Si-doped GaN layer.

9. The solar cell of claim 8, wherein the n-metal contact comprises a Ti/Al/Ni/Au grid contact.

10. The solar cell of claim 1, further comprising a p-metal contact on the Mg-doped GaN layer.

11. The solar cell of claim 10, wherein the p-metal contact comprises a Ni/Au grid contact.

12. The solar cell of claim 1, wherein a working temperature range of the solar cell is from room temperature to about 500° C.

13. The solar cell of claim 1, wherein an external quantum efficiency of the solar cell increases by at least a factor of 2 from room temperature to 500° C.

14. The solar cell of claim 1, wherein a temperature coefficient of the solar cell is greater than zero up to 350° C.

15. A solar cell comprising:
a nonpolar m-plane GaN substrate;
an n-type III-nitride layer;
a III-nitride active region; and
a p-type III-nitride layer.

16. The solar cell of claim 15, wherein the n-type III-nitride layer is in direct contact with the nonpolar m-plane GaN substrate.

17. The solar cell of claim 15, wherein the III-nitride active region is in direct contact with the nonpolar m-plane GaN substrate.

18. The solar cell of claim 15, wherein the III-nitride active region comprises one or more indium-containing quantum wells with barriers.

19. The solar cell of claim 15, wherein the p-type III-nitride layer is in direct contact with the III-nitride active region.

20. The solar cell of claim 15, wherein a working temperature range of the solar cell is from room temperature to about 500° C.

21. The solar cell of claim 15, wherein an external quantum efficiency of the solar cell increases by at least a factor of 2 from room temperature to 500° C.

22. The solar cell of claim 15, wherein a temperature coefficient of the solar cell is greater than zero up to 350° C.
